(19) United States
(12) Patent Application Publication
(10) Pub. No.: US 2024/0254389 A1
(43) Pub. Date: Aug. 1, 2024

(54) SILICON ETCHING SOLUTION, METHOD OF TREATING SILICON SUBSTRATE, AND METHOD OF MANUFACTURING SEMICONDUCTOR DEVICE

(71) Applicant: TOKUYAMA CORPORATION, Yamaguchi (JP)

(72) Inventors: Yoshiki SEIKE, Yamaguchi (JP); Tatsuya HITOMI, Yamaguchi (JP); Kohsuke NORO, Yamaguchi (JP)

(73) Assignee: TOKUYAMA CORPORATION, Yamaguchi (JP)

(21) Appl. No.: 18/394,206

(22) Filed: Dec. 22, 2023

(30) Foreign Application Priority Data
Dec. 23, 2022 (JP) 2022-207631

(51) Int. Cl. C09K 13/00; H01L 21/306

(52) U.S. Cl. CPC C09K 13/00; H01L 21/30604

(57) ABSTRACT

A silicon etching solution containing an organic alkaline compound and water, the silicon etching solution further containing a compound represented by Formula (1) below, wherein a content of the compound represented by Formula (1) is 100 mass ppm or more:

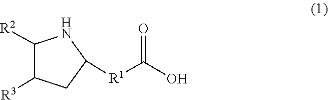

where R¹ is a single bond or a hydrocarbon group having carbon number from 1 to 5, R² and R³ are each independently a hydrogen atom, a halogen atom, a hydroxy group, an amino group, an acetyl group, a carboxy group, a silyl group, a boryl group, a nitrile group, a thio group, a seleno group, or a hydrocarbon group having carbon number from 1 to 10, and these groups optionally further have a substituent.

### TECHNICAL FIELD

The present invention relates to a silicon etching solution used in surface processing or in an etching step in manufacture of various silicon devices.

### BACKGROUND ART

Silicon (Si) is applied in various fields due to its excellent mechanical properties and electrical properties. Silicon is applied by utilizing its mechanical properties to valves; nozzles; print heads; semiconductor sensors for detecting various physical quantities, such as flow rate, pressure, or acceleration, (e.g., such as the diaphragm of a semiconductor pressure sensor or the cantilever of a semiconductor acceleration sensor); or the like. In addition, by utilizing its electrical properties, silicon is applied to various semiconductor devices, such as memory devices and logic devices, as a part of a metal wiring, or as a material for a gate electrode or the like.

The processing of silicon in the manufacture of semiconductor devices is mainly performed by etching treatment. Examples of etching methods include dry etching, such as reactive ion etching (RIE) or atomic layer etching (ALE); or wet etching with an acidic aqueous solution or an aqueous alkaline solution. Wet etching may often be inferior to dry etching in terms of fineness of processing. However, wet etching allows large-area processing and treatment of a plurality of wafers at the same time, and thus is superior to dry etching in terms of productivity. In particular, wet etching with an aqueous alkaline solution is suitably used in processes where emphasis is placed on productivity, such as etching away an unnecessary silicon layer entirely.

Several proposals have been made for etching solutions with high productivity, that is, etching solutions that can remove silicon at a high rate. Examples of such proposed etching solutions include an etching chemical solution prepared by adding an alkaline compound, an oxidizing agent, and a hydrofluoric acid compound into water and adjusting the pH of the resulting solution to 10 or higher (see Patent Document 1).

### PRIOR ART DOCUMENTS

### Patent Document

Patent Document 1: JP 2013-135081 A

### SUMMARY OF INVENTION

### Technical Problem

In general, the productivity of a wet etching step is improved by increasing the etching rate. In addition, in the production of semiconductor chips and the like, when silicon is wet-etched, the same or similar etchant cannot always be applied depending on the structures of the semiconductor chips to be manufactured and/or the like. Thus, there is a demand for technological richness, leading to selection depending on the circumstances.

Thus, an object of the present invention is to provide a novel etching solution that results from a new technical configuration and exhibits a high etching rate of silicon.

### Solution to Problem

The present inventors have conducted diligent studies to solve the above problems and have found that the etching rate of silicon is dramatically increased by using a silicon etching solution containing a compound having a specific structure, an organic alkaline compound, and water, and have completed the present invention.

That is, the configuration of the present invention is as follows.

Aspect 1. A silicon etching solution containing an organic alkaline compound and water,
the silicon etching solution further containing a compound represented by Formula (1) below, wherein a content of the compound represented by Formula (1) is 100 mass ppm or more:

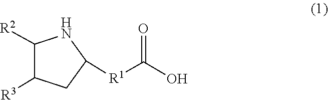

where R¹ is a single bond or a hydrocarbon group having carbon number from 1 to 5, R² and R³ are each independently a hydrogen atom, a halogen atom, a hydroxy group, an amino group, an acetyl group, a carboxy group, a silyl group, a boryl group, a nitrile group, a thio group, a seleno group, or a hydrocarbon group having carbon number from 1 to 10, and these groups optionally further have a substituent.

Aspect 2. The silicon etching solution according to aspect 1, wherein the silicon etching solution has a pH of 10.0 or higher and 14.0 or lower.

Aspect 3. The silicon etching solution according to aspect 1 or 2, wherein R¹ is a single bond.

Aspect 4. The silicon etching solution according to any one of aspects 1 to 3, wherein R² and R³ are each independently a hydrogen atom or a hydroxy group.

Aspect 5. The silicon etching solution according to any one of aspects 1 to 4, wherein the organic alkaline compound is a quaternary ammonium hydroxide.

Aspect 6. A method of treating a silicon substrate, the silicon substrate including at least one silicon material selected from the group consisting of a silicon wafer, a silicon single crystal film, a polysilicon film, and an amorphous silicon film, the method including a step of etching the silicon material using the silicon etching solution according to any one of aspects 1 to 5.

Aspect 7. A method of manufacturing a semiconductor device, the semiconductor device including a silicon substrate including at least one silicon material selected from the group consisting of a silicon wafer, a silicon single crystal film, a polysilicon film, and an amorphous silicon film, the method including a step of etching the silicon material using the silicon etching solution according to any one of aspects 1 to 5.

### Effects of Invention

According to the present invention, there can be provided a novel etching solution that results from a new technical configuration and exhibits a high etching rate of silicon. Thus, the present invention enables high-rate etching even in such cases where an accelerating technique (etching solution) known in the art is difficult to apply because of the material properties of a treatment target or the like.

### DESCRIPTION OF EMBODIMENTS

Hereinafter, the present invention will be described in detail. The following description is an example (representative example) of the present invention, and the present invention is not limited thereto. In addition, the present invention can be modified and implemented in any manner that does not depart from the gist of the present invention.

In the present specification, a numerical range expressed using “to” means “the described lower limit value or more and the described upper limit value or less” and means a range that includes numerical values described before and after “to” as the lower limit value and the upper limit value.

### <Silicon Etching Solution>

A silicon etching solution according to an embodiment of the present invention (hereinafter also described simply as “the etching solution”) is used for etching of silicon (crystalline silicon or amorphous silicon) in manufacture of semiconductor chips or the like. While etching of silicon is performed under acidic conditions or alkaline conditions, the etching solution according to the present embodiment is an aqueous alkaline solution (a pH of higher than 7) containing an organic alkaline compound and is used for etching under alkaline conditions.

### [Organic Alkaline Compound]

Higher alkalinity tends to increase the etching rate. Thus, the etching solution contains an organic alkaline compound. The organic alkaline compound is not particularly limited as long as it is an organic compound showing alkalinity (an organic compound showing alkalinity when dissolved in water). The organic alkaline compound is preferably one of various primary to tertiary amines, or a quaternary ammonium hydroxide. In terms of easily setting the pH to a range described later, a quaternary ammonium hydroxide is preferred. In the etching solution, these substances can be present in the form of a quaternary ammonium hydroxide or the like or can be present as their ions. Although the compound represented by Formula (1) described below can also be an organic alkaline compound depending on the aspect of R² and R³, in the present specification, the compound represented by Formula (1) is treated as the compound represented by Formula (1), not as an alkaline organic compound.

Specific examples of the quaternary ammonium hydroxide include tetramethylammonium hydroxide (TMAH), ethyltrimethylammonium hydroxide (ETMAH), tetraethylammonium hydroxide, tetrapropylammonium hydroxide, tetrabutylammonium hydroxide, trimethyl-2-hydroxyethylammonium hydroxide (choline hydroxide), dimethylbis(2-hydroxyethyl)ammonium hydroxide, methyltris(2-hydroxyethyl)ammonium hydroxide, phenyltrimethylammonium hydroxide, or benzyltrimethylammonium hydroxide. One of these can be used alone, or two or more can be used in combination.

The quaternary ammonium hydroxide with a smaller size tends to provide a higher etching rate. Among the above, a quaternary ammonium hydroxide having a total carbon number of 8 or less is preferred, and further a quaternary ammonium hydroxide having a total carbon number of 6 or less (such as TMAH or ETMAH) is particularly preferred.

In the etching solution, the quaternary ammonium hydroxide is usually dissociated and present as a hydroxide ion and a quaternary ammonium ion. In other words, the etching solution is usually a liquid containing a hydroxide ion for alkalinity and its counter ion (quaternary ammonium ion).

The etching solution containing an organic alkaline compound, such as a quaternary ammonium hydroxide, is usually alkaline, and the content of the organic alkaline compound can be appropriately adjusted according to a desired pH.

The content of the quaternary ammonium hydroxide in the etching solution is usually 35 mmol/kg or more although it depends on the types and contents of other components. A higher content of the organic alkaline compound leads to higher alkalinity, and the content is preferably 50 mmol/kg or more, more preferably 100 mmol/kg or more, and particularly preferably 150 mmol/kg or more. In addition, the content of the organic alkaline compound can be 1200 mmol/kg or less or can be 1000 mmol/kg or less, and sufficient performance can usually be obtained even with a content of 800 mmol/kg or less.

The content of the organic alkaline compound can be calculated from the pH when the content is low, but a large error is caused when the content is high. Thus, a method of calculating the content of the organic alkaline compound from the content of the counter cation measured with an ion chromatograph or the like is preferable in that it has high accuracy.

### [Compound Represented by Formula (1)]

The greatest feature of the silicon etching solution according to the present embodiment is that it contains a compound represented by Formula (1) below and having a pyrrolidine skeleton and a carboxy group (hereinafter also described as the compound (1)). The silicon etching solution containing the compound represented by Formula (1) greatly improves the etching rate of silicon compared with a silicon etching solution not containing the compound (1). In the etching solution, the compound (1) can be present in the form of the compound represented by Formula (1) or can be present as its ion (e.g., an ion formed by elimination of a hydrogen atom from the carboxy group or an ion formed by addition of a proton to the nitrogen atom).

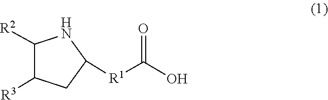

In Formula (1), R¹ is a single bond or a hydrocarbon group having carbon number from 1 to 5. R² and R³ are each independently a hydrogen atom, a halogen atom, a hydroxy group, an amino group, a carboxy group, an acetyl group, a silyl group, a boryl group, a nitrile group, a thio group, a seleno group, or a hydrocarbon group having carbon number from 1 to 10, and these groups optionally further have a substituent.

In Formula (1), indication of a bond with a hydrogen atom is omitted in portions where a substituent is not explicitly indicated (carbon atoms constituting the pyrrolidine group, specifically carbon atoms at position 2 (α-position), position 3, position 4, and position 5 of the pyrrolidine group). In the present specification, the carbon atom to which R1 is bonded among the carbon atoms constituting the ring of the pyrrolidine group is treated as position 2 (α-position).

In the compound (1) above, the nitrogen atom of the amino group at position 1 of the pyrrolidine group, and the carbon atom at position 3 of the pyrrolidine group have no substituent. Also, the carbon atom at position 2 (α-position) of the pyrrolidine group has no substituent other than —R¹COOH described in Formula (1). The present inventors presume that silicon is interposed between one of oxygen atoms in the carboxy group and the nitrogen atom contained at position 1 of the pyrrolidine group by intermolecular forces to form a cyclic structure having 5 or more atoms, and consequently, the back bond of silicon is weakened and the elimination of silicon is promoted. Thus, if these carbon atoms and the nitrogen atom have a substituent, steric hindrance when the cyclic structure is formed increases, thus failing to exert a desired effect. The carbon atoms at positions 4 and 5 of the pyrrolidine group have a small effect on steric hindrance, and thus a desired effect can be obtained regardless of whether these carbon atoms have a substituent.

R¹ in Formula (1) is a single bond or a hydrocarbon group having carbon number from 1 to 5 and is preferably a single bond from the viewpoint of improving the etching rate by reducing steric hindrance.

The hydrocarbon group is preferably an alkylene group from the viewpoint of reducing steric hindrance. In addition, the carbon number of the hydrocarbon group is not particularly limited as long as it is from 1 to 5, and it is more preferably from 1 to 3 and even more preferably 1. Furthermore, the hydrocarbon group can be linear or branched and is preferably linear.

R² and R³ in Formula (1) are each independently a hydrogen atom, a halogen atom, a hydroxy group, an amino group, an acetyl group, a carboxy group, a silyl group, a boryl group, a nitrile group, a thio group, a seleno group, or a hydrocarbon group having carbon number from 1 to 10. In addition, these groups (specifically, an amino group, an acetyl group, a silyl group, a boryl group, or a hydrocarbon group having carbon number from 1 to 10) can or cannot further have a substituent.

R² and R³ in Formula (1) are preferably each independently a hydrogen atom, a halogen atom, a hydroxy group, an amino group, an acetyl group, a carboxy group, a nitrile group, or a hydrocarbon group having carbon number from 1 to 10 from the viewpoint of ease of handling, and are more preferably each independently a hydrogen atom, a hydroxy group, an amino group, a carboxy group, or a hydrocarbon group having carbon number from 1 to 10 from the viewpoint of stability against alkali. In addition, from the viewpoint of improving the etching rate, R² and R³ in Formula (1) are even more preferably each independently a hydrogen atom, a hydrocarbon group having carbon number from 1 to 10, or a hydroxy group, and particularly preferably a hydrogen atom, a methyl group, an ethyl group, or a hydroxy group. From the viewpoint of preventing a decrease in the etching rate due to hydrophobic interaction with the silicon surface, R² and R³ are most preferably a hydrogen atom or a hydroxy group.

Furthermore, R² and R³ are not bonded to each other. That is, the compound (1) does not include an aspect in which R² and R³ are bonded to form a ring.

The substituent optionally included in R² and R³ is not particularly limited as long as the effects of the present invention is obtained, and examples include a halogen atom, a hydroxy group, an amino group, a carboxy group, an acetyl group, a silyl group, a boryl group, a nitrile group, a thio group, a seleno group, and a hydrocarbon group having carbon number from 1 to 10.

The type of halogen atom in R² and R³ and in the substituent optionally included in R² and R³ is not particularly limited and can be fluorine, chlorine, bromine, iodine, or the like. However, as will be described later, a component that promotes etching of silicon dioxide (SiO₂) under alkaline conditions is preferably not contained, and thus the halogen atom is preferably a halogen atom other than a fluorine atom, that is, chlorine, bromine, iodine, or the like.

The hydrocarbon group in R² and R³ and in the substituent optionally included in R² and R³ is preferably an alkyl group. In addition, the carbon number of the hydrocarbon group is not particularly limited as long as it is from 1 to 10, and from the viewpoint of improving the etching rate by reducing steric hindrance, the carbon number is preferably from 1 to 5, more preferably from 1 to 3, and even more preferably 1. Furthermore, the hydrocarbon group can be linear or branched and is preferably linear.

The content of the compound (1) in the etching solution is not particularly limited as long as it is 100 mass ppm or more (0.01 mass % or more) from the viewpoint of improving the etching rate, and from the viewpoint of further improving the etching rate and from the viewpoint of easily forming a homogeneous solution by dissolution, the content is preferably from 0.01 to 20.0 mass %, more preferably from 0.01 to 10.0 mass %, even more preferably from 0.1 to 7.0 mass %, and particularly preferably from 1.0 to 5.0 mass %.

The molar mass ratio of the organic alkaline compound to the compound (1) (compound (1)/organic alkaline compound) in the etching solution is, from the viewpoint of improving the etching rate, preferably from 0.001 to 5.00, more preferably from 0.10 to 4.00, even more preferably from 0.30 to 3.00, and particularly preferably from 0.80 to 2.00.

The compound (1) can be synthesized by a known method or known methods in combination, but a commercially available product thereof can be used.

### [Water]

The etching solution according to the present embodiment contains water as an essential component. When water is not contained in the etching solution, etching would not proceed. The content of water in the etching solution is not particularly limited, and water can be contained in such a content as in a typical etching solution. The content is preferably 30 mass % or more, more preferably 50 mass % or more, even more preferably 60 mass % or more, and particularly preferably 75 mass % or more although it depends on the types and amounts of other components. In addition, the upper limit is not particularly limited as long as other components can be contained in desired amounts and can be usually 99.5 mass % or less, and a sufficient effect can be obtained with 99 mass % or less.

### [Additional Substance]

The silicon etching solution according to the present embodiment can contain a substance (hereinafter also described as an “additional substance”) other than the organic alkaline compound, the compound (1), and water described above as long as the effects of the present invention are obtained. Examples of the additional substance include a substance that can be contained in a typical silicon etching solution, and examples include a metal corrosion inhibitor, an organic solvent, a catalyst, a complexing agent, a chelating agent, a surfactant, an antifoaming agent, a pH adjuster, a stabilizer, a solubilizer, or a precipitation inhibitor. A substance corresponding to these substances but corresponding to the organic alkaline compound or compound (1) described above is handled as the organic alkaline compound or compound (1) described above. In the case where an additional substance is contained in the etching solution, even if the etching solution needs to contain a substance that reduces the etching rate of silicon for a certain purpose, the etching rate can be improved by the addition of the compound (1) as described above. Thus, this can reduce the effect on the decrease in the etching rate due to the incorporation of the additional substance.

In addition, when a treatment solution, such as an etching solution, contains a metal, it may often adversely affect an object to be treated (not limited to a silicon surface to be etched).

Thus, the etching solution preferably contains no metal (less than the detection limit). More specifically, it is preferred to at least avoid a metal from being contained in a concentration exceeding the impurity level. More preferably, the content of each of Ag, Al, Ba, Ca, Cd, Co, Cr, Cu, Fe, K, Li, Mg, Mn, Na, Ni, Pb, and Zn is 1 mass ppm or less, and particularly preferably, the content of each metal above is 1 mass ppb or less. The metals listed here are metals considered to affect the quality of a chemical solution used in semiconductor manufacturing.

In addition, when silicon is etched in manufacture of semiconductor chips, it is often undesirable to etch a silicon dioxide portion (surface) included in a semiconductor chip. Thus, the etching solution preferably contains no component that promotes etching of silicon dioxide (SiO₂) under alkaline conditions. A typical example of such a component is a fluoride ion. Thus, the organic alkaline compound and/or compound (1) described above preferably contains no fluorine atom.

In addition, a hydrophobic substance is easily adsorbed to silicon. Thus, a hydrophobic substance if contained in the etching solution may be highly likely to reduce the etching rate. Thus, the content of a hydrophobic substance in the etching solution is preferably 1 mass ppm or less, more preferably 1 mass ppb or less, and even more preferably, it is not contained (less than the detection limit).

A cleaning agent and/or the like contained in a treatment solution for polishing and the like is generally likely to contain a hydrophobic etching solution. Thus, the etching solution according to the present embodiment preferably does not contain a cleaning liquid, an organic solvent, or the like.

In addition, for the reason that the compound (1) is decomposed into ammonia, an amine compound, formic acid, carbon dioxide, or the like by oxidative cleavage, the etching solution preferably contains no oxidizing agent.

Furthermore, the etching solution is preferably a homogeneous solution in which all components contained are dissolved. Moreover, in terms of preventing contamination during etching, the number of particles having a size of 200 nm or greater is preferably 100/mL or less, more preferably 50/mL or less, and particularly preferably 10/mL or less.

In etching of silicon, a higher alkali concentration (thus higher alkalinity) tends to increase the etching rate. Thus, the pH of the etching solution according to the present embodiment is preferably 10.0 or higher and 14.0 or lower, 10.5 or higher and 13.5 or lower, even more preferably 11.0 or higher and 13.5 or lower, and particularly preferably 12.0 or higher and 13.4 or lower. This pH refers to a value measured at 24° C. by the glass electrode method.

### <Method of Manufacturing Silicon Etching Solution>

The method of manufacturing the silicon etching solution described above is not particularly limited and can be a manufacturing method including a step of mixing the organic alkaline compound, the compound (1) described above, and water. Examples include a method in which the organic alkaline compound and compound (1) described above are mixed with water to give desired concentrations and dissolved to produce a homogeneous solution.

For raw materials for the organic alkaline compound and the compound (1), materials with the lowest possible amounts of the metal impurity described above and/or an insoluble impurity are preferably used. Materials obtained by purifying commercially available products as necessary by recrystallization, column purification, ion exchange purification, distillation, sublimation, filtration treatment, or the like can be used.

When a quaternary ammonium hydroxide is employed as the organic alkaline compound, an extremely high purity product of a quaternary ammonium hydroxide manufactured and sold for semiconductor manufacturing according to the type thereof is preferably used. Such a high purity quaternary ammonium hydroxide for semiconductor manufacturing is typically sold as a solution, such as an aqueous solution. In manufacture of the silicon etching solution, this solution is used as it is and mixed with components, such as water and the compound (1).

Also, for the water, high purity water with low impurity content is preferably used. The amount of impurities can be evaluated by the electrical resistivity. Specifically, the electrical resistivity of the water is preferably 0.1 Mf-cm or more, more preferably 15 MO cm or more, and even more preferably 18 MO-cm or more. Such water with low impurity content can be easily manufactured and obtained as ultrapure water for semiconductor manufacturing. Furthermore, ultrapure water also has significantly low content of impurities that do not affect (or contribute little to) the electrical resistivity and is highly suitable for the etching solution.

In addition, the etching solution can contain an additional substance as necessary as described above.

Furthermore, when a quaternary ammonium hydroxide is employed as the organic alkaline compound, the etching solution can contain a halogen salt of a quaternary ammonium, such as tetramethylammonium chloride, ethyltrimethylammonium iodide, dodecyltrimethylammonium bromide, or decyltrimethylammonium bromide.

As described above, the etching solution preferably contains no fluoride ion. Thus, the etching solution preferably does not contain a fluoride, such as ammonium fluoride or tetramethylammonium fluoride, even though such a compound is known as a component of a chemical solution for semiconductor manufacturing. Likewise, the etching solution preferably does not contain a PF₆ salt, a BF₄ salt, or the like.

In manufacture of the etching solution, after the components are mixed and dissolved, the resulting solution is preferably passed through a filter with a pore size of several nanometers to several tens of nanometers to remove particles. The treatment of passing the solution through a filter can be performed multiple times as necessary.

Furthermore, in manufacture of the etching solution, various other known treatments for providing necessary physical properties in manufacture of chemical solutions used in semiconductor manufacturing can be applied, such as reducing dissolved oxygen by bubbling with an inert gas, such as high purity nitrogen gas.

For mixing and dissolution (and storage), it is preferred to use a container and a device formed of or coated with a material from which a contaminant is less likely to be dissolved into the etching solution. Examples of such a material include materials known for the inner wall of containers for chemical solutions for semiconductor manufacturing, specifically polyfluoroethylene or high purity polypropylene. The container and device are suitably cleaned in advance.

### <Application and Method of Use>

The silicon etching solution described above can be used in a method of treating a silicon substrate. A method of treating a silicon substrate, which is another embodiment of the present invention, is a method of treating a silicon substrate including at least one silicon material selected from the group consisting of a silicon wafer, a silicon single crystal film, a polysilicon film, and an amorphous silicon film (hereinafter also described as a “silicon wafer and/or the like”), which includes a step of etching the silicon material using the silicon etching solution described above.

Thus, the silicon etching solution described above can also be suitably used in a method of manufacturing a silicon device. A method of manufacturing a silicon device, which is another embodiment of the present invention, is a method of manufacturing a silicon device including a silicon substrate including at least one silicon material selected from the group consisting of a silicon wafer, a silicon single crystal film, a polysilicon film, and an amorphous silicon film, which includes a step of etching the silicon material using the silicon etching solution described above.

In the present specification, the silicon wafer, silicon single crystal film, polysilicon film, and amorphous silicon film are collectively referred to as a silicon material.

In addition, the silicon single crystal film includes one made by epitaxial growth.

The etching using the silicon etching solution described above is performed by wet etching. That is, the silicon etching solution is brought into contact with a substrate having a silicon (Si) surface, and a treatment of etching the Si surface can be performed accordingly. On the other hand, the etching solution according to the present embodiment usually does not etch silicon dioxide (SiO₂) or silicon nitride (SiN) although it depends on a component optionally blended. Thus, examples of a target to be treated using the etching solution include a substrate having: at least one surface selected from a silicon nitride surface and a silicon dioxide surface; and a silicon surface (including a silicon single crystal, polysilicon, or amorphous silicon surface); on the surface to be treated. The substrate can include a film of various types and/or the like. Examples of the substrate include a substrate in which silicon and silicon dioxide are alternately layered, and a structure in which a pattern is formed on a silicon single crystal using polysilicon, silicon nitride, or silicon dioxide.

A method of treating a substrate using the silicon etching solution described above includes:
a substrate holding step of holding a substrate in a horizontal posture, and
a treatment solution supplying step of supplying the etching solution described above to a main surface of the substrate while the substrate is rotated about a vertical rotation axis passing through a central portion of the substrate.

Another method of treating a substrate using the silicon etching solution described above includes:
a substrate holding step of holding a plurality of substrates in an upright posture, and
a step of immersing the substrates in an upright posture in the above-mentioned etching solution stored in a treatment vessel.

The silicon etching solution described above is used in manufacture of a silicon device including a step of selectively etching silicon contained in a silicon wafer and/or the like by supplying the etching solution when etching the silicon wafer, in manufacture of various silicon composite semiconductor devices including a silicon wafer and/or the like, especially a silicon wafer and/or the like containing at least one selected from silicon nitride and silicon dioxide.

Wet etching can be performed only by bringing a material to be etched into contact with the silicon etching solution, and an electrochemical etching method can also be employed, in which a constant potential is applied to the material to be etched. The electrochemical etching method includes an anodic oxidation method, in which a silicon material is immersed in the silicon etching solution, and then a positive voltage is applied.

The temperature of the silicon etching solution described above during etching using the silicon etching solution can be appropriately determined from a range of 20 to 95° C. in view of a desired etching rate, productivity, the shape and surface conditions of silicon after etching, and the like, and the temperature is suitably in a range of 35 to 90° C.

For etching using the silicon etching solution described above, the etching can be performed with degassing in vacuum or under reduced pressure, or bubbling with an inert gas. Such an operation can suppress or reduce the increase in dissolved oxygen during etching and stabilize the etching rate accordingly.

### EXAMPLES

Hereinafter, the present invention will be described in further detail by examples, but the present invention is not limited to these examples.

Experimental methods/evaluation methods in examples and comparative examples are described as follows.

### Experiment I

### Method of Preparing Etching Solution

A tetramethylammonium hydroxide (TMAH) aqueous solution (2730 mmol/kg, available from Tokuyama Corporation) commercially available for semiconductor manufacturing was diluted with ultrapure water and mixed to produce a homogeneous chemical solution. Then, various additives were added to the solution to prepare etching solutions according to each example and comparative example having the composition listed in Table 1. The forms of the additives used in the preparation are described as follows.

### Forms of Additives Used in Preparation

Proline, hydroxyproline, thioproline, α-methylproline, N-methylproline, glycine, and (2S,3aS,7aS)-octahydro-1H-indole-2-carboxylic acid: pure powder
Hexanoic acid: liquid

In Examples 1 to 10 and Comparative Examples 1 to 11, the organic alkaline compound, TMAH, was blended in a final concentration adjusted to 260 mmol/kg (2.38 mass %).

In addition, in Comparative Examples 12 and 13, the organic alkaline compound, TMAH, was blended in a final concentration adjusted to 54 mmol/kg (0.5 mass %) and 1.1 mmol/kg (0.01 mass %), respectively.

### (Measurement Method of pH of Etching Solution)

The pH of the etching solution was measured under a temperature condition of 24° C. using a tabletop pH meter F-73 available from Horiba, Ltd. and a pH electrode 9632-10D for strongly alkaline samples available from Horiba, Ltd.

### (Evaluation Method of Etching Rate (Unit: Nm/Min))

The silicon etching solutions each having a solution temperature heated to the treatment temperature described in Table 1 (Tables 1-1 and 1-2) were prepared each in an amount of 100 g. A substrate (silicon (100 plane) film, available from Globalnet Co., Ltd.) obtained by epitaxially growing silicon (Si) on a silicon-germanium (SiGe) substrate with a size of 2×1 cm was immersed in each silicon etching solution for 15 seconds in the case of a solution temperature of 43° C. or for 5 seconds in the case of a solution temperature of 70° C. Then, in examples and comparative examples in which nitrogen bubbling was applied, during etching, the solution was stirred at 600 rpm, and nitrogen bubbling at 0.2 L/min was continuously performed. Nitrogen bubbling at 0 L/min in Table 1 indicates that nitrogen bubbling was not applied. Then, the film thicknesses of each substrate before and after etching were measured with a spectroscopic ellipsometer, and the etched amount of the silicon film was determined from the difference in the film thicknesses before and after the etching treatment. Then, the etching rate (R′ 100) of the silicon (100 plane) film at the given temperature was determined by dividing the etched amount by the etching time.

In Table 1, the description “-” indicates that a compound was not contained, that the measurement was not performed, or the like.

### [Table 1-1]

TABLE 1-1

| | Silicon etching solution | | | | | | | | | | | |
|---|---|---|---|---|---|---|---|---|---|---|---|---|
| | | | | | | | Molar | | | | | |
| | | | | | | | ratio of | | | Treat- | | Si(100) |
| | Organic alkaline | | | Compound (1) or | | | compound | Water | | meant | | etching |
| | compound | | | other compound | | | (1)/organic | Content | | temper- | Nitrogen | rate |
| | | Content | Content | | Content | Content | alkaline | (mass | | ature | bubbling | (nm/ |
| | Type | (mass %) | (mol/kg) | Type | (mass %) | (mol/kg) | compound | %) | pH | (° C.) | (L/min) | min) |
| Comparative | TMAH | 2.38 | 0.26 | — | — | — | — | 97.62 | 13.4 | 43 | 0.2 | 79 |
| Example 1 | | | | | | | | | | | | |
| Comparative | TMAH | 2.38 | 0.26 | Proline | 0.001 | 0.00009 | 0.0003 | 97.62 | 13.4 | 43 | 0.2 | 80 |
| Example 2 | | | | | | | | | | | | |
| Example 1 | TMAH | 2.38 | 0.26 | Proline | 0.01 | 0.0009 | 0.003 | 97.61 | 13.4 | 43 | 0.2 | 94 |
| Example 2 | TMAH | 2.38 | 0.26 | Proline | 0.1 | 0.01 | 0.033 | 97.52 | 13.4 | 43 | 0.2 | 89 |
| Example 3 | TMAH | 2.38 | 0.26 | Proline | 1 | 0.09 | 0.333 | 96.62 | 13.0 | 43 | 0.2 | 123 |
| Example 4 | TMAH | 2.38 | 0.26 | Proline | 3 | 0.26 | 0.998 | 94.62 | 12.1 | 43 | 0.2 | 152 |
| Example 5 | TMAH | 2.38 | 0.26 | Proline | 5 | 0.43 | 1.663 | 92.62 | 10.9 | 43 | 0.2 | 156 |
| Example 6 | TMAH | 2.38 | 0.26 | Proline | 10 | 0.87 | 3.327 | 87.62 | 10.3 | 43 | 0.2 | 106 |
| Comparative | TMAH | 2.38 | 0.26 | — | — | — | — | 97.62 | 13.4 | 43 | 0 | 80 |
| Example 3 | | | | | | | | | | | | |
| Example 7 | TMAH | 2.38 | 0.26 | Proline | 3 | 0.26 | 0.998 | 94.62 | 12.1 | 43 | 0 | 156 |
| Example 8 | TMAH | 2.38 | 0.26 | Proline | 5 | 0.43 | 1.663 | 92.62 | 10.9 | 43 | 0 | 229 |
| Comparative | TMAH | 2.38 | 0.26 | — | — | — | — | 97.62 | 13.4 | 70 | 0 | 560 |
| Example 4 | | | | | | | | | | | | |
| Example 9 | TMAH | 2.38 | 0.26 | Proline | 3 | 0.26 | 0.998 | 94.62 | 12.1 | 70 | 0 | 761 |

TABLE 1-2

| | Silicon etching solution | | | | | | | | | | | |
|---|---|---|---|---|---|---|---|---|---|---|---|---|
| | | | | | | | Molar | | | | | |
| | | | | | | | ratio of | | | Treat- | | Si(100) |
| | Organic alkaline | | | Compound (1) or | | | compound | Water | | meant | | etching |
| | compound | | | other compound | | | (1)/organic | Content | | Temper- | Nitrogen | rate |
| | | Content | Content | | Content | Content | alkaline | (mass | | ature | bubbling | (nm/ |
| | Type | (mass %) | (mol/kg) | Type | (mass %) | (mol/kg) | compound | %) | pH | (° C.) | (L/min) | min) |
| Example 10 | TMAH | 2.38 | 0.26 | L-Hydroxyproline | 3 | 0.23 | 8.876 | 94.62 | 12.3 | 43 | 0.2 | 154 |
| Comparative | TMAH | 2.38 | 0.26 | Thioproline | 3 | — | — | 94.62 | 12.3 | 43 | 0.2 | 52 |
| Example 5 | | | | | | | | | | | | |
| Comparative | TMAH | 2.38 | 0.26 | α-Methylproline | 3 | — | — | 94.62 | 12.2 | 43 | 0.2 | 46 |
| Example 6 | | | | | | | | | | | | |
| Comparative | TMAH | 2.38 | 0.26 | N-Methylproline | 3 | — | — | 94.62 | 12.3 | 43 | 0.2 | 13 |
| Example 7 | | | | | | | | | | | | |
| Comparative | TMAH | 2.38 | 0.26 | Glycine | 3 | — | — | 94.62 | 12.1 | 43 | 0.2 | 70 |
| Example 8 | | | | | | | | | | | | |
| Comparative | TMAH | 3.38 | 0.26 | Glycine | 3 | — | — | 92.62 | 10.9 | 43 | 0.2 | 7 |
| Example 9 | | | | | | | | | | | | |
| Comparative | TMAH | 2.38 | 0.26 | Hexanoate acid | 1 | — | — | 96.62 | 12.9 | 43 | 0.2 | 42 |
| Example 10 | | | | | | | | | | | | |
| Comparative | TMAH | 2.38 | 0.26 | (2S,3aS,7aS)- | 1 | — | — | 96.62 | 13.3 | 43 | 0.2 | 78 |
| Example 11 | | | | Octahydro-1H- | | | | | | | | |
| | | | | indole-2- | | | | | | | | |
| | | | | carboxylic acid | | | | | | | | |
| Comparative | TMAH | 0.5 | 0.05 | — | — | — | — | 99.5 | 13 | 43 | 0.2 | 61 |
| Example 12 | | | | | | | | | | | | |
| Comparative | TMAH | 0.01 | 0.001 | — | — | — | — | 99.99 | 11 | 43 | 0.2 | 21 |
| Example 13 | | | | | | | | | | | | |

From Table 1, it was found that an etching solution with a high etching rate can be obtained by containing 100 mass ppm or more of proline in the etching solution. It was found that an etching solution with a high etching rate can be obtained regardless of the difference in solution temperature and the presence or absence of nitrogen bubbling.

Furthermore, addition of 3 mass % of L-hydroxyproline, which has only a slight steric hindrance and slight effect on hydrophilicity, also made it possible to obtain an etching solution with a high etching rate. However, the etching rates were each unchanged or decreased for the etching solutions to which thioproline, α-methylproline, N-methylproline, or (2S,3aS,7aS)-octahydro-1H-indole-2-carboxylic acid, which is another proline analogue; glycine, which has no proline skeleton; or hexanoic acid, which has no amino group; was added.

1. A silicon etching solution comprising an organic alkaline compound and water,
the silicon etching solution further comprising a compound represented by Formula (1), wherein a content of the compound represented by Formula (1) is 100 mass ppm or more: 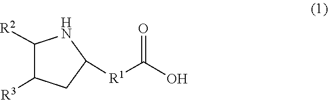
where R¹ is a single bond or a hydrocarbon group having carbon number from 1 to 5, R² and R³ are each independently a hydrogen atom, a halogen atom, a hydroxy group, an amino group, a carboxy group, an acetyl group, a silyl group, a boryl group, a nitrile group, a thio group, a seleno group, or a hydrocarbon group having carbon number from 1 to 10, and these groups optionally further have a substituent.

2. The silicon etching solution according to claim 1, wherein the silicon etching solution has a pH of 10.0 or higher and 14.0 or lower.

3. The silicon etching solution according to claim 1, wherein R¹ is a single bond.

4. The silicon etching solution according to claim 1, wherein R² and R³ are each independently a hydrogen atom or a hydroxy group.

5. The silicon etching solution according to claim 1, wherein the organic alkaline compound is a quaternary ammonium hydroxide.

6. A method of treating a silicon substrate, the silicon substrate comprising at least one silicon material selected from the group consisting of a silicon wafer, a silicon single crystal film, a polysilicon film, and an amorphous silicon film,
the method comprising etching the silicon material using the silicon etching solution according to claim 1.

7. A method of manufacturing a semiconductor device, the semiconductor device comprising a silicon substrate comprising at least one silicon material selected from the group consisting of a silicon wafer, a silicon single crystal film, a polysilicon film, and an amorphous silicon film,
the method comprising etching the silicon material using the silicon etching solution according to claim 1.
